(19) United States
(12) Patent Application Publication
(10) Pub. No.: US 2026/0318193 A1
(43) Pub. Date: Oct. 15, 2026

(54) METHOD FOR PREDICTING A LOG DURING DRILLING OF A WELL

(71) Applicant: IFP Energies nouvelles, Rueil-Malmaison (FR)

(72) Inventors: Antoine BOUZIAT, RUEIL-MALMAISON CEDEX (FR); Christophe CORNET, RUEIL-MALMAISON CEDEX (FR); Jean-Francois LECOMTE, RUEIL-MALMAISON CEDEX (FR); Patrick RASOLOFOSAON, RUEIL-MALMAISON CEDEX (FR)

(21) Appl. No.: 19/119,122

(22) PCT Filed: Sep. 27, 2023
(86) PCT No.: PCT/EP2023/076777

§ 371 Date: Apr. 8, 2025

(30) Foreign Application Priority Data
Oct. 10, 2022 (FR) FR2210350

(51) Int. Cl. E21B 49/00; E21B 44/00; G06F 30/28

(52) U.S. Cl. CPC E21B 49/00; E21B 44/00; G06F 30/28; E21B 2200/20; E21B 2200/22

(57) ABSTRACT

The invention concerns a method for predicting a well log beyond the depth of a drill bit. From at least one learning curve of the log acquired in a learning well of greater depth than the drill bit, matched with a curve of the log acquired in the well, a model is constructed to predict the log in the well by a supervised machine learning method. For each learning curve, a composite learning curve of the portion of the learning curve matched with the curve of the well to the drill bit and of the portion of the learning curve matched with the other learning curves beyond the drill bit is constructed. The values of the well log beyond the depth of the drill bit are predicted by applying the model to the composite learning curves.

### CROSS-REFERENCE TO RELATED APPLICATIONS

Reference is made to PCT/EP2023/076777 filed Sep. 27, 2023, and French Application No. 2210350, filed Oct. 10, 2022, which are incorporated herein by reference in their entirety.

### BACKGROUND OF THE INVENTION

### Field of the Invention

The present invention notably concerns the field of geosteering that is intended to guide well drilling operations in an underground formation, according to measurement results (generally well log and seismic data) acquired in real time. More specifically, the invention concerns a method of predicting the values of a well log beyond the drill bit, simultaneously with well drilling, notably in order to guide well drilling beyond the depth of the drill bit, according to the prediction of the well log values.

### Description of the Prior Art

Geosteering orients in real time the direction of a wellbore, from an initial plan, determined from a previously constructed model of the underground formation structures, and from well log data acquired while drilling. Thus, in the process of drilling a borehole, geosteering adjusts the borehole position (inclination and azimuth angles) on the fly, to reach one or more geological targets. In the field of petroleum exploration, the goal is generally to orient the direction of the well towards a zone of the underground formation comprising hydrocarbons. In mature zones, geosteering can be used to maintain a wellbore in a particular reservoir section to minimize gas or water breakthrough and to maximize the economic production from the well.

Geosteering requires upstream construction of an underground formation model, also referred to as geological model. These models, which are well known and widely used in the petroleum industry, need to be representative of the boundaries of geological layers and of the constitutive rocks of these layers. This type of subsoil model is most often represented in a computer, by a mesh or grid, generally three-dimensional with each grid cell being characterized by one or more petrophysical properties (facies, porosity, permeability, etc.). Constructing such a model, that must notably reflect the geometry of the geological layer boundaries, requires at least interpretation of a seismic image obtained after seismic acquisition and seismic processing. Filling of the cells with values also requires analysis techniques for both seismic data (via stratigraphic inversion for example) and well log data (gamma ray logs, sonic logs, apparent density logs, electric logs or well image logs for example). Thus, acquiring a geologic model is a very long step requiring the intervention of several experts.

While the borehole is drilled according to the data deduced from the geological model, new geological data is collected by logging tools. Generally, a conventional configuration of tools lowered into a well comprises direction and inclination sensors, as well as a gamma ray logging tool. Other conventional measurements are neutron density, seismic prospecting, downhole pressure measurements. Measurements performed while drilling generally have some differences compared to what is expected from the model. The geological model is then updated with the new geological data, as well as the well plan in order to reach the corrected geological targets.

The following documents are mentioned in the description hereafter:
Berg, C. R., & Newson, A. C. (2013 August). Geosteering using true stratigraphic thickness. In SPE/AAPG/SEG Unconventional Resources Technology Conference. OnePetro.
Lallier, F., Caumon, G., Borgomano, J., Viseur, S., & Antoine, C. (2009). Dynamic time warping for stochastic stratigraphic well correlation. Search and Discovery Article, 40473.
Naville, C., Serbutoviez, S., Throo, A., Vincké, O., & Cecconi, F. (2004). Seismic while drilling (SWD) techniques with downhole measurements, introduced by IFP Energies nouvelles and its partners in 1990-2000. Oil & Gas Science and Technology, 59(4), 371-403.
Sakoe, H., & Chiba, S. (1978). Dynamic programming algorithm optimization for spoken word recognition. IEEE transactions on acoustics, speech, and signal processing, 26(1), 43-49.
Song, F., & Toksoz, M. N. (2009). Model-guided Geosteering for Horizontal Drilling. Massachusetts Institute of Technology. Earth Resources Laboratory.
Wang, Z. (2017). Integrated geosteering workflow for optimal well trajectory. Doctoral dissertation, Memorial University of Newfoundland.

Geosteering methods have developed significantly in recent years.

The document (Berg and Newson, 2013) that describes a geosteering method allowing using only gamma ray logs is known. Indeed, this method compares a gamma ray log in a horizontal well with the corresponding log in a neighboring vertical (pilot) well. According to this method, the log recorded from the horizontal well is at least one of compressed and inverted until the deformed log thus can be best matched with the log from the pilot well. Compression is necessary because relatively small stratigraphic intervals in the pilot well are traversed over much larger distances in the horizontal well. Inversion is also necessary because the wellbore may cover a given stratigraphic interval from bottom to top and from top to bottom. The scale factor that has enabled matching of the two logs is directly related to the inclination of the horizontal well. However, although this method does not require much input data, the method is based, as in any known geosteering technique, on real well log measurements performed on the fly, which are only strictly valid down to the drill bit.

Wang, 2017, which concerns an integrated geosteering methodology for determining an optimum well trajectory combining geostatistical algorithms, well log measurements while drilling and reservoir simulation methods, is also known. More precisely, the goal of this integrated technique is to explore a relatively fast updating process for oilfield exploration without complex structures. It comprises a procedure for using geostatistical realizations to control the drilling process and to optimize the well trajectory in relation to the production performances. The statistical reservoir realizations are updated with the logging while drilling data throughout the drilling process. However, as in all known geosteering techniques, this method is based on real well log measurements that are available only down to the depth of the drill bit.

Naville et al., 2004 concerns a seismic while drilling technique. This technique allows, among other things, imaging ahead of the drill bit using the bit noise as the seismic source. It is thus possible, with this technique, to know, upstream from the drill bit, changes likely to impact the initial well plan. However, this method has the disadvantage of requiring at least a seismic recording system for, on the one hand, the echoes from the geological formations ahead of the drill bit, and on the other hand the vibrations of the bit itself, to eliminate during post-processing the signature of this seismic source in order to refine the images. This technique requires heavier implementation than methods based on simple well logs.

Song and Toksoz, 2009 describe a method similar to logging while drilling, but it using real seismic sources instead of drill bit noise. This technique therefore has the disadvantage of requiring both seismic sources and sensors in the field, and it also requires potentially significant seismic processing.

### SUMMARY OF THE INVENTION

The present invention allows these drawbacks to be overcome. Indeed, the method according to the invention predicts values of a well log beyond the depth of a drill bit, and such values can be directly used by conventional geosteering methods instead of the well log data as really measured, but down to the depth of the drill bit only. Predictions ahead of the drill bit may allow identification, beforehand and while drilling, future lithology changes (passage of the clayey cap rock into the reservoir for example), which are important data that can be immediately used as input data in any geosteering method.

The present invention concerns a method of predicting, while drilling a well in an underground formation, the values of a well log beyond the depth of the bit used for drilling the well, notably in order to guide drilling of the well beyond the depth of the bit used for drilling the well, according to the prediction.

The method is characterized by at least the following steps being carried out:
A. acquiring a learning curve of the well log according to the depth in at least one learning well, using a logging tool, the depth of the learning well extending beyond the depth of the bit used for drilling the well;
B. acquiring a curve of the log according to the depth in the well, using the logging tool, the second curve being acquired down to the depth of the bit used for drilling the well;
C. for each of the learning curves of the log, matching, down to the depth of the bit used for drilling the well, the learning curve of the log acquired in the learning well with the curve of the log acquired in the well, using a method of similarity search between signals recorded at different scales;
D. constructing a model for predicting the log in the well by use of a supervised machine learning method that is trained on a learning base comprising the learning curves of the log matched down to the depth of the bit used for drilling the well with the curve acquired in the well, and the curve of the log according to the depth in the well;
E. optionally, if a plural learning curves of the log has been acquired, matching the learning curves with one another using the method of similarity search between signals recorded at different scales;
F. for each of the learning curves, constructing a composite learning curve of the log, made up on the one hand of the portion of the learning curve of the log matched with the curve of the log down to the depth of the bit, and on the other hand of the portion of the learning curve, optionally matched with the other learning curves when a plurality of learning curves of the log has been acquired, for depths beyond the depth of the bit; and
G. predicting the values of the log in the well at least beyond the depth of the bit used for drilling the well by applying the model for predicting the log in the well constructed in step D to the composite learning curves.

According to an implementation of the invention, the method of similarity searching between signals recorded at different scales can be the dynamic time warping method.

According to an implementation of the invention, the log can be a gamma ray log.

According to an implementation of the invention, the supervised machine learning method can be selected from among the following list: random forest method, extremely randomized decision trees, and gradient boosting.

According to an implementation of the invention, steps B to G can be repeated for a succession of depths of the bit used for drilling the well.

The invention further concerns a geosteering drilling method wherein the following steps are carried out for each depth of a succession of depths of the bit used for drilling the well:
a) predicting values of a well log beyond the depth of the bit used for drilling the well, using the method for predicting, while drilling a well in an underground formation, the values of a log beyond the depth of the bit used for drilling the well as described above,
b) determining a drilling direction of the well for depths beyond the depth of the bit used for drilling the well, according to at least the values of the log predicted beyond the depth of the bit used for drilling the well.

Furthermore, the invention concerns a computer program product downloadable from at least one of a communication network, recorded on a computer-readable medium and/or processor executable, comprising program code instructions for carrying out steps C to G of the method as described above, when the program is executed on a computer.

### BRIEF DESCRIPTION OF THE DRAWINGS

Other features and advantages of the method according to the invention will be clear from reading the description hereafter of embodiments given by way of non-limitative example, with reference to the accompanying figures wherein:

FIG. 1A and FIG. 1B show gamma ray log curves as a function of depth, measured in a learning well and in a target well respectively;

FIG. 1C illustrates the matching of homologous events of the curves of FIGS. 1A and 1B detected using a method of similarity search between signals recorded at different scales;

FIG. 1D and FIG. 1E show the difference between the curves of FIGS. 1A and 1B, respectively before and after matching the homologous events;

FIG. 2A, FIG. 2B and FIG. 2C show gamma ray log curves measured in a target well and in two learning wells respectively;

FIG. 3A shows a gamma ray log curve predicted by the model according to the invention in the target well of FIG. 2A, and a gamma ray log curve really measured in this target well; and

FIG. 3B shows the difference between the two curves of FIG. 3A.

### DETAILED DESCRIPTION OF THE INVENTION

The invention concerns a method of predicting, while drilling a well in an underground formation, the values of a well log beyond the depth of the well drilling bit, notably in order to guide drilling of the well according to the prediction.

According to the invention and as described more precisely hereafter, prediction of the values of a log is performed for a well referred to as “target well” hereafter, at a time of advance of the drill bit in this well, in other words, at a depth of the well drilling bit. The goal is to predict the values of a well log, which has been measured down to the depth of the drill bit of the target well, beyond the depth of the drill bit of the target well. As described hereafter, this prediction is achieved from a curve of the log measured in the target well down to the depth of the drill bit, and from at least one curve of the same log measured in another well of the underground formation, referred to as “learning well” hereafter, extending beyond the depth of the drill bit. Thus, the method according to the invention aims to predict values of a log in a target well, beyond the depth of the drill bit, from logs measured in learning wells extending beyond the depth of the drill bit. Preferably, the learning well(s) traverse the same underground formation as the target well. Alternatively, a learning well may traverse a geological analog of the underground formation.

Generally, a well log results from a measurement performed with a logging tool (or a sonde) lowered in a well. The result of a logging measurement is a curve representative of the variations of a characteristic of a geological formation as a function of depth in the well. Examples of well logs are gamma ray logs, sonic logs, apparent density logs, electric logs or well image logs.

According to a preferred implementation of the invention, the predicted log can be the gamma ray log, also referred to as GR log. GR logs measure the natural radioactivity in underground formations. They can be used to identify lithologies and to correlate depth intervals from one well to another. Sandstones and carbonates without clay have low radioactive material concentrations and they have weak GR responses. As the clay content increases, the GR response increases due to the radioactive material concentration in clays. The prediction of the gamma ray response in a well ahead of the drill bit can thus allow to informing in advance of future lithology changes (passage of a clayey cap rock into a reservoir for example). This makes it possible to reduce drilling hazards and costs, and to improve the location of the well. It can be noted that the method according to the invention can be applied to any well log indiscriminately. The GR log is preferred here due to its high potential for geosteering.

The method according to the invention comprises at least the following steps:
1) Acquiring a well log learning curve in at least one learning well;
2) Acquiring a well log curve in the target well;
3) Matching each learning curve with the target well curve down to the depth of the drill bit in the target well;
4) Constructing a model for predicting the log in the target well;
5) Matching learning curves with one another (option);
6) Constructing a learning curve of the composite log; and
7) Predicting the log in the target well beyond the depth of the drill bit.

The method according to the invention is implemented for a depth of the well drilling bit. According to an implementation of the invention that is described more broadly hereafter, step 1) can be carried out only once, beforehand, and steps 2) to 7) of the method can be repeated as the target well is being drilled, for example for a succession of depths of the well drilling bit.

According to an implementation of the invention, in cases where several well logs are measured in the target well, steps 1) to 7) of the method according to the invention can be repeated, at a given drill bit depth, for each log of the plurality of logs to be predicted, in order to take account of the plurality of predicted logs, notably for guiding drilling of the well beyond the drill bit depth.

The method according to the invention comprises steps carried out by information technology (computer), notably steps 3) to 7). The computer can comprise data processing means (processor) and data storage means (memory), as well as an input/output interface for data input and results output.

According to an embodiment of the invention, steps 2) to 7) can be carried out in real time during a drilling operation, to possibly implement a geosteering drilling method.

The steps of the method according to the invention are detailed hereafter.

### 1) Acquiring a Well Log Learning Curve in at Least One Learning Well

This step consists acquires a learning curve of the well log of interest as a function of depth in at least one learning well, using a logging tool. This acquisition can be performed while drilling the learning well or after the learning well has been drilled.

According to the invention, a learning well is a well whose depth extends beyond the depth of the target well drilling bit (preferably beyond at least 10 meters, more preferably beyond at least 20 meters), to predict the log for depths beyond the drill bit depth. It is clear that a learning curve acquired in a learning well according to the invention comprises log values for depths beyond the depth of the target well drilling bit.

The method according to the invention requires at least one learning well, preferably at least 2 and more preferably at least 5. The invention is particularly configured to be relevant from the petroleum exploration phase, during which few wells are available. It is clear that the log prediction will be all the more reliable as the number of learning wells is large.

It is clear that the learning curves of the log of interest can have depth scales that are distinct from one another, and also from the depth scale of the log curve measured in the target well. Indeed, the geological layers of an underground formation are rarely plane and horizontal. Moreover, the thickness of the geological layers may vary laterally. Thus, a log record corresponding to values measured as a function of depth, a value representative of the same geological event (a geological layer boundary for example), may not be necessarily at the same depth in one well and in another.

### 2) Acquiring a Well Log Curve in the Target Well

This step acquires a curve of the log of interest as a function of depth in the target well, using the logging tool already used in step 1). It is clear that it may not necessarily be strictly the same tool, but any tool suited for measuring this log.

According to the invention, the well log curve is acquired down to the depth of the target well drilling bit, knowing that it is precisely desired to predict the log beyond the drill bit depth. As discussed above, the log curve recorded in the target well can have a depth scale distinct from the depth scale of the learning curves. In other words, a value representative of the same geological event (a geological layer boundary for example) may not necessarily be at the same depth in the target well as in the learning well(s).

3) Matching Each Learning Curve with the Target Well Curve Down to the Depth of the Drill Bit in the Target Well

This step matches each learning curve with the curve measured in the target well down to the depth of the well drilling bit, by use of a method of similarity search between signals recorded at different scales. More precisely, such a method of similarity search between signals recorded at different scales matches the events of a curve with homologous events of another curve.

In other words, this step matches the events of a curve measured in a learning well with homologous events of the curve measured in the target well, down to the depth of the drill bit in the target well. It is clear that a learning curve whose events are scaled to the curve measured in the target well is then obtained. In other words, matching is performed by considering the curve measured in the target well as the reference.

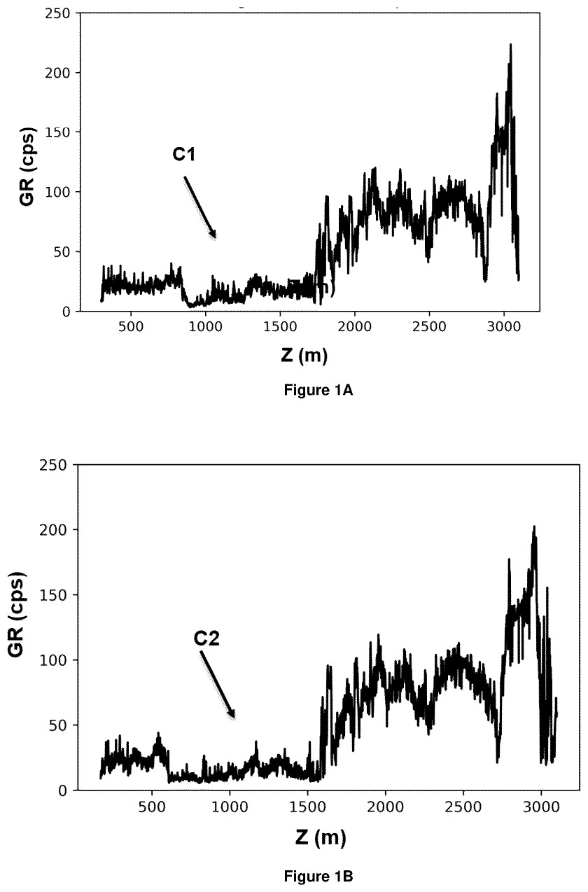

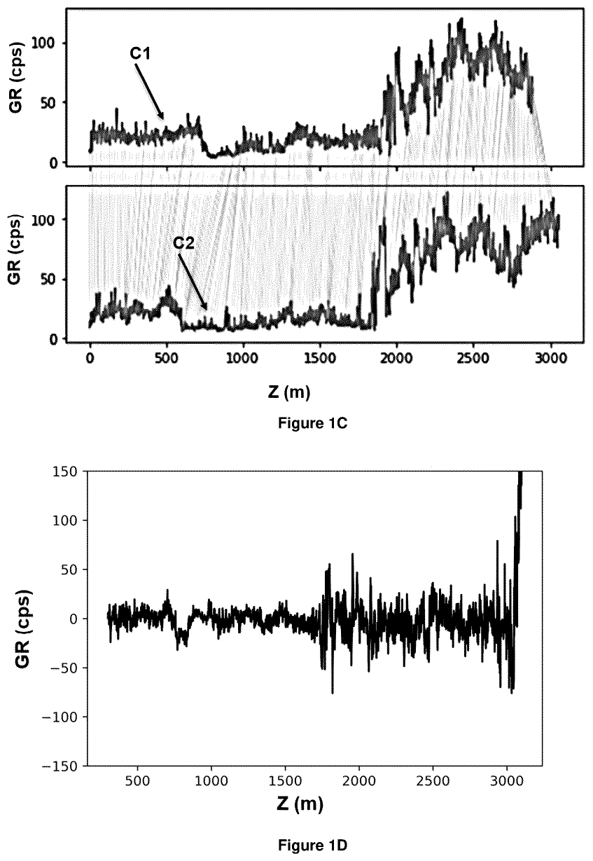

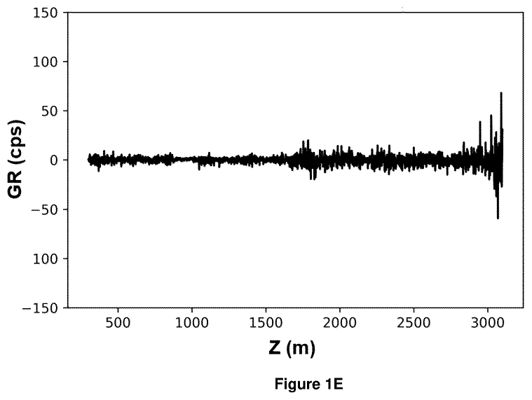

FIGS. 1A to 1E illustrate the principle of this matching. More precisely, FIGS. 1A and 1B respectively show a curve C1 and a curve C2 of the gamma ray GR measurement as a function of depth Z, curve C1 was measured in a learning well and curve C2 was measured in the target well. It can be observed that curves C1 and C2 have homologous events that are however offset along the x-axis. FIG. 1C illustrates, with gray lines, matching of the homologous events of curves C1 and C2 detected by a method of similar searching between signals recorded at different scales (in this case, the dynamic time warping method described below). It can be observed that some homologous events were recorded at very close depths (essentially vertical gray lines), whereas other homologous events were recorded at distant depths (oblique gray lines). FIGS. 1D and 1E show the difference between curves C1 and C2, before and after matching respectively. It can be observed in these figures that the difference between curves C1 and C2 is clearly less significant after matching than before matching. More precisely, the standard deviation of the difference between curves C1 and C2 drops from 16% to less than 4% of the maximum amplitude of the gamma ray GR measurement, after matching.

According to an implementation of the invention, the dynamic time warping (DTW) method can be used for matching. This method was described for the first time in the document (Sakoe and Chiba, 1978). For clarity reasons, it is possible to use a simple acoustic analogy to get a practical idea of DTW. Consider two singers, one rather good and the other rather mediocre. The latter sings off-key and respects neither the rhythm (sequence of time intervals between the sung notes) nor the key (absolute pitch of the notes), nor the tempo (speed of execution) of the song. When listening to two recordings of the same song by these two singers, even an untrained ear can easily detect a certain similarity and especially several differences between these recordings. Not only does DTW quantify with precision the difference between these recordings, but it also and especially provides automatically time matching of the homologous events observed in these two recordings. It is also clear that this technique, although called dynamic time warping, can be applied to any signal whose x-axis is different from time, in this case whose x-axis corresponds to depth.

Sakoe and Chiba, 1978 describes the original implementation of the DTW method as described hereafter. Let X(i) and Y(j) be two signals (time signals here, but the technique can be applied to any signal) to be matched. Function C(i,j) representing the cost density of warping for a pair (i,j) is defined by:

$$C ( i , j ) = Abs ( X ( i ) - Y ( j ) ) + Min ( C ( i - 1 , j - 1 ) , C ( i - 1 , j ) , C ( i , j - 1 ) )$$

knowing that the first elements are given by the relations:

$$C ( 1 , 1 ) = Abs ( X ( 1 ) - Y ( 1 ) )$$

$$C ( 1 , j ) = Abs ( X ( 1 ) - Y ( j ) ) + C ( 1 , j - 1 ) )$$

$$C ( i , 1 ) = Abs ( X ( i ) - Y ( 1 ) ) + C ( i - 1 , 1 ) ) .$$

The warping function of indices i and j homologous to signals X and Y respectively is defined as follows: Let N be the number of samples of signals X and Y. It is assumed that the pairs of points (X(1), Y(1)) and (X(N),Y(N)) are the first and last homologous points respectively. Then, starting from the Nth homologous point, the (N−1)th pair of homologous points is the one whose cost density function corresponds to Min (C(N, N−1), C(N−1, N−1), C(N−1, N)), and so on recurrently. Thus, the (i−1)th pair of homologous points is the one corresponding to Min (C(i, i−1), C(i−1, i−1), C(i−1, i), and so on up to the first pair of points (X(1), Y(1)). From the warping function, a signal Y matched with signal X is determined for example. It is clear that any improvement of this technique can be used.

Alternatively, the method of similarity search between signals recorded at different scales described in Lallier et al., 2009, which concerns a declination of the DTW method applied to the correlation of geological horizons between wells, can be used. This method differs from the (Sakoe and Chiba, 1978) method not only by the fact that the curves considered are in depth and not in time, but mainly by the fact that it uses a stochastic technique of stratigraphic well correlation, the goal being to generate automatically several possible well correlation sets which account for the interpretations made along the well trajectories. In practice, the correlation probability of each stratigraphic marker and the interval identified along the well path is calculated by use of:
available information on the interpreted well (paleobathymetry, lithology, for example),
some reference correlation lines from clear first-order stratigraphic boundaries,
a sedimentological scenario for the zone studied, and
sedimentological concepts deemed applicable.

Using these probabilities, several possible well correlation sets are generated stochastically in a modified version of the Sakoe and Chiba, 1978 DTW algorithm.

### 4) Constructing a Model for Predicting the Log in the Target Well

This step constructs a model for predicting the log in the target well, using a supervised machine learning method that is trained on a learning base comprising:
the learning curve(s) matched, down to the depth of the well drilling bit, with the log curve measured in the target well. These curves correspond to the input data of the supervised machine learning method during this training phase;
the curve measured in the target well. This curve corresponds to the output to be reproduced by the supervised machine learning method during this training phase.

Thus, in this step, a supervised machine learning method is trained on the curves measured in the learning wells, after these curves have been matched with the curve measured in the target well, so that the model allows predicting the log values in the target well. A model for log prediction in the target well is thus obtained. It is clear here that this is a regression problem since values of a continuous variable (the log measurement) are determined.

According to an implementation of the invention, any of the following methods can be used as the supervised machine learning method: random forest method, extremely randomized decision trees, gradient boosting, support vector machine, generalized linear model, and generalized additive model or feed forward neural network for deep learning. These methods are very simple to implement, even for a non-expert, notably because they only require few parameters: the maximum computing time (typically only a few minutes are sufficient, 200 seconds for example), and the distribution among the data that will be really used for learning and the data that will be used for learning validation (typically 80% and 20% respectively).

According to a preferred implementation of the invention, the supervised machine learning method can be selected from among the following: random forest method, extremely randomized decision trees, and gradient boosting. It was indeed found that, for a certain number of application examples for which the method according to the invention has been implemented, the aforementioned three methods often rank among the most effective in terms of prediction reliability.

According to an even more preferred implementation of the invention, the gradient boosting method can be used. Indeed, it was found that, for the application examples wherein the method according to the invention was implemented, this method was statistically the one leading most often to the best predictions. Gradient boosting uses two concepts, ensemble machine learning and machine learning boosting. In the ensemble machine learning technique, the learning models are adjusted to the data individually or combined in an ensemble. An ensemble is a combination of simple individual models that creates together a more powerful new model. Besides, machine learning boosting is a particular method of creating ensembles as follows. First of all, it starts with the adjustment to the data of an initial model (by linear regression or decision tree for example). The next model is then constructed to make the prediction more accurate in cases where the first model performs poorly. The combination of these two models is better than either of the previous two models alone. This process known as boosting is repeated several times, each successive model trying to correct the gaps in the predictions of the previous combined models. Finally, gradient boosting is a particular type of machine learning boosting. The general principle is based on the fact that the best possible next model, when combined with the previous models, minimizes the global prediction error. The term “gradient boosting” is due to the fact that the target results for each case are defined according to the gradient of the error relative to the prediction. More precisely, each new model takes a step in the direction that minimizes the prediction error, in the space of the possible predictions for each learning case.

5) Matching Learning Curves with One Another (Option)

This step is optional and it is carried out only if plural log learning curves have been acquired. In this optional step, the learning curves are matched with one another, using a method of similarity search between signals recorded at different scales.

In other words, in this step, if there are several learning wells and if a log curve has been recorded in each of these learning wells, the curves recorded for each of these wells are matched. Indeed, each log curve has its own scale, due to the fact that the geological layers are not plane, horizontal, and laterally isometric.

This step can be carried out using the dynamic time warping technique DTW described above, or the technique described in the aforementioned document (Lallier, 2009) for matching the learning curves recorded for each learning well.

Advantageously, matching is performed by selecting as the reference the learning well whose distance to the target well is the shortest, preferably whose distance to the target well is the shortest as regards the depth of the target well drilling bit. This allows matching of the learning curves with one another with, in principle (depending on the stratigraphy), the least difference in scale in relation to the curve acquired in the target well.

### 6) Constructing a Learning Curve of the Composite Log

This step, for each learning curve constructs a learning curve of the composite log, made up, on the one hand, of the portion of the learning curve matched with the curve down to the depth of the drill bit, and on the other hand of a portion of the learning curve, optionally matched with the other learning curves when a plural log learning curves have been acquired, for depths beyond the drill bit depth.

In other words, for each learning well, a composite curve is constructed, whose part above the drill bit depth corresponds to the curve measured in this learning well and is matched with the curve measured in the target well, and whose part below the drill bit depth corresponds to:
if a single log learning curve has been acquired to the part of the curve measured in this learning well for depths beyond the drill bit depth;
if several log learning curves have been acquired: to the part of the curve measured in this learning well and matched with the other learning curves.

At the end of this step, for each learning well, a composite learning curve consistent with the target well above the drill bit, and consistent with the possible other wells below the drill bit.

### 7) Predicting the Log in the Target Well Beyond the Depth of the Drill Bit

This step predicts the log values in the target well, beyond the depth of the well drilling bit, by applying the log prediction model constructed in step 4) to the composite learning curves constructed in step 6).

In other words, the regression model constructed in step 4) is applied to the composite learning curves constructed in step 6), which comprise values of the log beyond the depth of the target well drilling bit, for predicting log values in the target well beyond the depth of the target well drilling bit.

A curve of the log of interest predicted in the target well, comprising values at least for the depths beyond the depth of the target well drilling bit, is thus obtained.

According to an implementation of the invention, it is possible to predict the log of interest in the target well beyond the depth of the target well drilling bit, and also for depths within the depth of the target well drilling bit. This may also enable checking the quality of the model constructed in step 4) in the part within the depth of the target well drilling bit, by comparing the values of the predicted log with those of the measured log.

According to an implementation of the invention, it is possible to predict the log of interest in the target well only beyond the depth of the target well drilling bit. This allows reduction of the execution time of the method according to the invention, and thus providing a log curve predicted more rapidly, which is advantageous with the goal of real-time target well drilling geosteering.

The method according to the invention thus predicts the values of a log in the target well at least beyond the depth of the well drilling bit.

The method can be advantageously implemented simultaneously with drilling of this well, to guide drilling of the well beyond the depth of the well drilling bit, according to the prediction of the log values. Indeed, geosteering methods according to the prior art use real log values, measured down to the drill bit depth only, whereas the method according to the invention determines predicted log values beyond the drill bit depth, which can therefore be directly used by geosteering methods.

According to an implementation of the invention, step 1) can be carried out only once, and steps 2) to 7) can be carried out as the target well is being drilled, for example for a succession of depths. This makes possible gradual refining of the log prediction for the deepest depths in the target well, and when the logging measurements performed in the target well go deeper as drilling advances.

According to an implementation of the invention, steps 2) to 7) of the method can be repeated for a succession of depths of the well drilling bit, for example every 10 m, preferably every 5 m, and more preferably every 1 m. Alternatively, steps 2) to 7) of the method can be repeated for a succession of time intervals while drilling the target well, for example every 60 minutes, preferably every 30 minutes, and more preferably every 10 minutes, these durations being predefined according to the well drilling rate (typically between 1.5 m/h and 15 m/h).

It can be noted that, for the application examples on which the method according to the invention has been implemented, the execution time of steps 3) to 7) was of the order of 3 minutes with an Intel® Xeon® CPU E5-1620 v3 @ 3.50 GHz (16.0 Go RAM memory) type processor, which is well below the conventional drill bit feed rate over a few meters thus the log prediction can thus be made nearly in real time.

The invention further concerns a geosteering drilling method wherein the following steps are carried out for each depth of a succession of depths of the bit used for drilling the well:
a) predicting values of a well log beyond the depth of the bit used for drilling the well, using the method for predicting, while drilling a well in an underground formation, the values of a log beyond the depth of the well drilling bit as described above,
b) determining the drilling direction of the well for depths beyond the depth of the well drilling bit, according to at least the log values predicted beyond the depth of the well drilling bit.

Those skilled in the art have perfect knowledge of the requirements for carrying out step b) above since, in the field of geosteering, they determine the well drilling direction from really measured log curves, whereas in this case, it is sufficient to consider the log curves predicted according to the invention in addition.

According to an implementation of the invention, it is possible to apply, in step b), the technique described in the aforementioned document (Berg and Newson, 2013), which concerns a geosteering method allowing use of only gamma ray logs, but by using the log curves predicted according to the invention beyond the depth of the well drilling bit, and not only the really measured log curves.

According to another implementation of the invention, it is possible to alternatively apply the technique described in the aforementioned document (Wang, 2017), which concerns an integrated geosteering methodology combining geostatistical algorithms, logging while drilling techniques and reservoir simulation methods. According to this implementation, the method described in document (Wang, 2017) can be applied using the log curves predicted according to the invention beyond the depth of the well drilling bit, and not only the really measured log curves.

According to an implementation of the invention, in step b), at least the inclination and azimuth angles of the well trajectory are determined for depths extending between 10 and 20 m beyond the drill bit depth, for each depth of the well drilling bit of the succession of depths of the well drilling bit.

### Example

The features and advantages of the method according to the invention will be clear from reading the application example hereafter.

More precisely, the method according to the invention was applied to an offshore underground formation in Western Australia, more specifically in the Northern Carnarvon Basin, considered as the premier hydrocarbon basin of Australia.

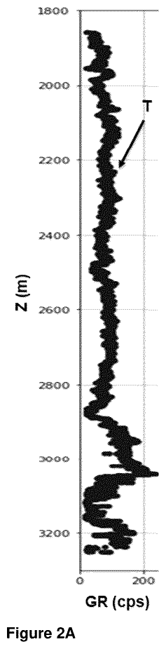

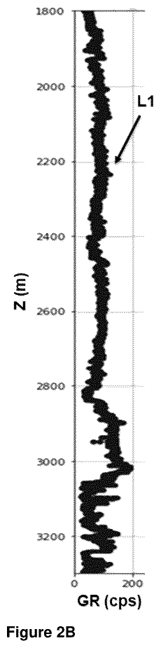

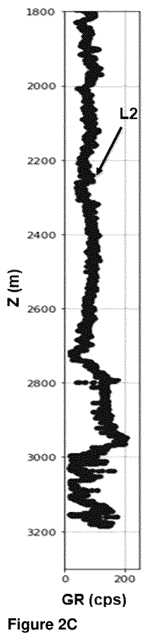

FIG. 2A shows a gamma ray GR log curve measured in a target well, denoted by T hereafter (curve denoted by T in FIG. 2A). The target well penetrates a 6-metre column of oil in the sandstones of the Barrow group. This well further penetrates water-bearing sands, with a thin column of oil, marls and shales.

We have two learning wells denoted by Li (i=1 to 2), which are about 3.5 km and 8 km from target well T respectively. FIGS. 2B and 2C show the gamma ray GR log curves measured in well L1 and in well L2 respectively (curves denoted by L1 and L2 in FIGS. 2B and 2C).

We have gamma ray values for depths extending to at least 3200 m: 3277 m for target well T, 3295 m for well L1 and 3200 m for well L2. In order to illustrate the reliability of the method according to the invention, it is desired to predict the values of the GR log for depths extending beyond 3100 m, and the prediction quality is controlled by use of the GR log curve really measured in target well T for depths from 3100 m to 3200 m. In other words, in order to validate the method according to the invention, the method according to the invention is applied by considering that the drill bit depth in the target well is 3100 m.

According to step 3) described above, the GR curves of wells L1 and L2 are matched with the GR curve of target well T down to the depth of 3100 m, using the method described in the aforementioned document (Sakoe and Chiba, 1978).

Moreover, the method according to the invention is implemented using the gradient boosting method as the supervised machine learning method. Training of this machine learning method is performed on curves GR of wells L1 and L2 matched with the GR curve of target well T down to the depth of 3100 m, and on the GR curve of target well T. A model for predicting a log (a GR log here) in target well T according to step 4) described above is thus obtained.

Then, according to step 5) described above, the GR curves of wells L1 and L2 are matched with one another, by taking as the reference well L1, which is the closest learning well to target well T.

According to step 6) described above, composite learning curves are generated for learning wells L1 and L2, made up of the portion of the GR curves of these wells down to the depth of 3100 m after matching thereof with target well T, and of the portion of the GR curves of wells L1 and L2 beyond the depth of 3100 m after matching thereof.

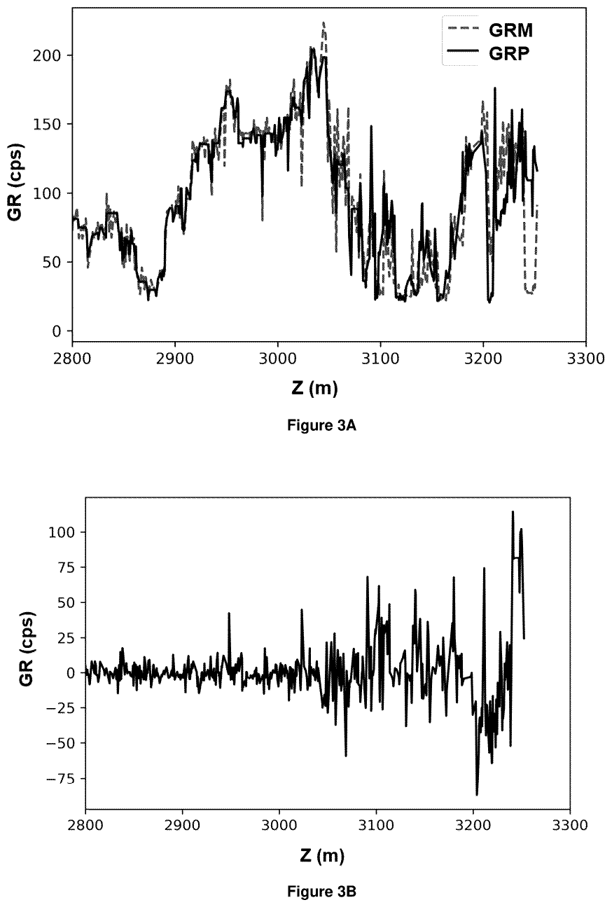

The model for predicting a log in the target well constructed according to step 4) is then applied to the composite learning curves constructed as described above in step 6). FIG. 3A shows the GRP curve that is the GR curve predicted by the model, as well as the GRM curve that is the GR curve really measured, and FIG. 3B shows the difference between these two curves.

It can be observed that the predicted GRP curve is perfectly coherent with the really measured GRM curve from 3100 m to 3200 m, i.e. down to a depth of 100 m beyond the depth to which the model was trained (drill bit depth in the method according to the invention). Indeed, in this depth range, the error quantified by the standard deviation of the difference between the GR curve predicted by the model according to the invention and the really measured GR curve is less than 2% of the maximum amplitude of the really measured GR curve. Beyond 3200 m, errors increase significantly, and they exceed 10% on average of the maximum amplitude of the real GR measurement.

Thus, application of the method according to the invention has allowed reliable prediction of a well log (a GR log here) beyond the depth of the well drilling bit, over a hundred meters. This is very advantageous because, for conventional drilling rates, typically between 1.5 m/h and 15 m/h, this corresponds to more than 6 hours drilling to reach this limit. Now, the computing time of the method according to the invention is significantly shorter, typically of the order of a few minutes. It is thus possible to relaunch the method according to the invention as the drill bit advances in the well, and to update the model as soon as the new logs are available. Thus, updating the log prediction can be done nearly in real time. Alternatively, it may be sufficient to update the prediction model of a log and to predict a new log by using this prediction model updated preferably every 10 m at least, or preferably every 5 m of advance of the drill bit in the target well.

Thus, the present invention allows prediction of log responses at depths that have not yet been reached by the wellbore, typically at multidecametric distances ahead of the bit while drilling, notably in order to guide the drilling operation down to such distances from these predictions, and not only from real measurements as in the prior art.

1-7. (canceled)

8. A method of predicting, while drilling a well in an underground formation, values of a well log beyond a depth of a bit used for drilling the well, to guide drilling of the well beyond the depth of the bit used for drilling the well according to the prediction, comprising steps of:
A. acquiring a learning curve of the well log according to a depth in at least one learning well, using a logging tool, the depth of the learning well extending beyond the depth of a bit used for drilling the well;
B. acquiring a curve of the log according to depth in the well, using the logging tool, the second curve being acquired down to the depth of a bit used for drilling the well;
C. for each of the learning curves of the log, matching, down to the depth of the bit used for drilling the well, the learning curve of the log acquired in the learning well with the curve of the log acquired in the well, using a method of similar search between signals recorded at different scales;
D. constructing a model for predicting the log in the well by use of a supervised machine learning method trained on a learning base comprising the learning curves of the log matched down to the depth of the bit used for drilling the well with the curve acquired in the well, and the curve of the log according to the depth in the well;
E. optionally, if plural learning curves of the log have been acquired, matching the learning curves with one another using the method of similar search between signals recorded at different scales;
F. for each of the learning curves, constructing a composite learning curve of the log, made up on the one hand of a portion of the learning curve of the log matched with the curve of the log down to a depth of the bit, and the portion of the learning curve, optionally matched with the other learning curves when plural learning curves of the log have been acquired, for depths beyond the depth of the bit; and
G. predicting the values of the log in the well at least beyond the depth of the bit used for drilling the well by applying the model for predicting the log in the well constructed in step D to the composite learning curves.

9. A method as claimed in claim 8, wherein the method of similar search between signals recorded at different scales is a dynamic time warping method.

10. A method as claimed in claim 8, wherein the log is a gamma ray log.

11. A method as claimed in claim 9, wherein the log is a gamma ray log.

12. A method as claimed in claim 8, wherein the supervised machine learning method is selected from a random forest method, extremely randomized decision trees, and gradient boosting.

13. A method as claimed in claim 9, wherein the supervised machine learning method is selected from a random forest method, extremely randomized decision trees, and gradient boosting.

14. A method as claimed in claim 10, wherein the supervised machine learning method is selected from a random forest method, extremely randomized decision trees, and gradient boosting.

15. A method as claimed in claim 11, wherein the supervised machine learning method is selected from a random forest method, extremely randomized decision trees, and gradient boosting.

16. A geosteering drilling method in accordance with claim 8, wherein, for each depth of a succession of depths of the bit used for drilling the well:
a) values of a well log beyond the depth of the bit used for drilling the well are predicted using the method for predicting, while drilling a well in an underground formation, values of a log beyond depth of the bit used for drilling the well; and
b) a drilling direction of the well is determined for depths beyond depth of the bit used for drilling the well, according to at least the values of the log predicted beyond the depth of the bit used for drilling the well.

17. A geosteering drilling method in accordance with claim 9, wherein, for each depth of a succession of depths of the bit used for drilling the well:
a) values of a well log beyond the depth of the bit used for drilling the well are predicted using the method for predicting, while drilling a well in an underground formation, values of a log beyond depth of the bit used for drilling the well; and
b) a drilling direction of the well is determined for depths beyond depth of the bit used for drilling the well, according to at least the values of the log predicted beyond the depth of the bit used for drilling the well.

18. A geosteering drilling method in accordance with claim 10, wherein, for each depth of a succession of depths of the bit used for drilling the well:
a) values of a well log beyond the depth of the bit used for drilling the well are predicted using the method for predicting, while drilling a well in an underground formation, values of a log beyond depth of the bit used for drilling the well; and
b) a drilling direction of the well is determined for depths beyond depth of the bit used for drilling the well, according to at least the values of the log predicted beyond the depth of the bit used for drilling the well.

19. A geosteering drilling method in accordance with claim 11, wherein, for each depth of a succession of depths of the bit used for drilling the well:
a) values of a well log beyond the depth of the bit used for drilling the well are predicted using the method for predicting, while drilling a well in an underground formation, values of a log beyond depth of the bit used for drilling the well; and
b) a drilling direction of the well is determined for depths beyond depth of the bit used for drilling the well, according to at least the values of the log predicted beyond the depth of the bit used for drilling the well.

20. A geosteering drilling method in accordance with claim 12, wherein, for each depth of a succession of depths of the bit used for drilling the well:
a) values of a well log beyond the depth of the bit used for drilling the well are predicted using the method for predicting, while drilling a well in an underground formation, values of a log beyond depth of the bit used for drilling the well; and
b) a drilling direction of the well is determined for depths beyond depth of the bit used for drilling the well, according to at least the values of the log predicted beyond the depth of the bit used for drilling the well.

21. A geosteering drilling method in accordance with claim 13, wherein, for each depth of a succession of depths of the bit used for drilling the well:
a) values of a well log beyond the depth of the bit used for drilling the well are predicted using the method for predicting, while drilling a well in an underground formation, values of a log beyond depth of the bit used for drilling the well; and
b) a drilling direction of the well is determined for depths beyond depth of the bit used for drilling the well, according to at least the values of the log predicted beyond the depth of the bit used for drilling the well.

22. A geosteering drilling method in accordance with claim 14, wherein, for each depth of a succession of depths of the bit used for drilling the well:
a) values of a well log beyond the depth of the bit used for drilling the well are predicted using the method for predicting, while drilling a well in an underground formation, values of a log beyond depth of the bit used for drilling the well; and
b) a drilling direction of the well is determined for depths beyond depth of the bit used for drilling the well, according to at least the values of the log predicted beyond the depth of the bit used for drilling the well.

23. A geosteering drilling method in accordance with claim 15, wherein, for each depth of a succession of depths of the bit used for drilling the well:
a) values of a well log beyond the depth of the bit used for drilling the well are predicted using the method for predicting, while drilling a well in an underground formation, values of a log beyond depth of the bit used for drilling the well; and
b) a drilling direction of the well is determined for depths beyond depth of the bit used for drilling the well, according to at least the values of the log predicted beyond the depth of the bit used for drilling the well.

24. A geosteering drilling method in accordance with claim 16, wherein, for each depth of a succession of depths of the bit used for drilling the well:
a) values of a well log beyond the depth of the bit used for drilling the well are predicted using the method for predicting, while drilling a well in an underground formation, values of a log beyond depth of the bit used for drilling the well; and
b) a drilling direction of the well is determined for depths beyond depth of the bit used for drilling the well, according to at least the values of the log predicted beyond the depth of the bit used for drilling the well.

25. A computer program product downloadable from at least one of a communication network and recorded on a computer-readable medium; and processor executable, program code instructions for carrying out steps C to G of the method as claimed in claim 8, when the program is executed on a computer.
